(19) United States
(12) Patent Application Publication
(10) Pub. No.: US 2009/0168325 A1
(43) Pub. Date: Jul. 2, 2009

(54) Disk fixing structure

(75) Inventors: Yao Tsung Yeh, Hsinchu (TW); Chi Yu Tsang, Miaoli (TW)

Correspondence Address: Haverstock & Owens LLP, 162 North Wolfe Road, Sunnyvale, CA, 94086, US

(73) Assignee: MUSTEK TECHNOLOGY CO., LTD.

(21) Appl. No.: 12/156,324

(22) Filed: May 30, 2008

(30) Foreign Application Priority Data
Dec. 26, 2007 (TW) 096222199

(51) Int. Cl. H05K 5/00; G06F 1/16

(52) U.S. Cl. 361/679.33

(57) ABSTRACT

A disk fixing structure containing a disk having at least one hole in a bottom thereof is provided. The disk fixing structure includes a first fixing device and a second fixing device. The first fixing device has a surface disposing thereon the disk, at least one protrusion mounted on the surface for being lodged in the at least one hole, and a plurality of first engaging elements arranged on each of two opposite edges of the surface which correspond to two sides of the disk. The second fixing device has two lateral plates opposite to each other, and a plurality of second engaging elements disposed on each of the two lateral plates, and engaging with the plurality of first engaging elements.

### FIELD OF THE INVENTION

The present invention is related to a disk fixing structure, and more particularly to a disk fixing structure without screwing.

### BACKGROUND OF THE INVENTION

Nowadays, the electronic device, such as the desktop computer, the DVD player or the versatile HDD player, generally includes a hard disk arranged therein. The traditional assembling method is that the hard disk is screwed to the electronic device through screw holes in two sides of the hard disk. The mentioned assembly method can provide stable assembly for the hard disk in the electronic device thereby avoid the vibration issue while reading out the hard disk. However, the process for assembling or disassembling the hard disk by using the mentioned assembly method is complicated and the operating time for assembling or disassembling the hard disk would be increased accordingly.

Besides, there is a further study to provide the improved designs for simplifying the process for assembling or disassembling the hard disk in the electronic device and reducing the operating time. Nevertheless, it is inadequate for these designs to keep stability for the hard disk in the electronic device.

Therefore, the purpose of the present invention is to develop a disk fixing structure without screwing to deal with the above situations encountered in the prior art.

### SUMMARY OF THE INVENTION

It is therefore a first aspect of the present invention to provide a disk fixing structure without screwing to simplify the process for assembling or disassembling a disk in an operating device. Further, the stability for the disk in the operating device would be kept. Furthermore, the strengths for bearing collision and vibration in the operating device would be greatly enhanced.

It is therefore a second aspect of the present invention to provide a disk fixing structure by providing two fixing devices for containing a disk, in which the fixing devices are combined by engaging with each other and the fixing devices further include at least one protrusion and a resilient element to assist the security for containing the disk.

According to a third aspect of the present invention, a disk fixing structure containing a disk having at least one hole in a bottom thereof is provided. The disk fixing structure includes a first fixing device and a second fixing device. The first fixing device has a surface disposing thereon the disk, at least one protrusion mounted on the surface for being lodged in the at least one hole, and a plurality of first engaging elements arranged on each of two opposite edges of the surface which correspond to two sides of the disk. The second fixing device has two lateral plates opposite to each other, and a plurality of second engaging elements disposed on each of the two lateral plates, and engaging with the plurality of first engaging elements.

Preferably, the first fixing device is a base and further has a plurality of limit plates disposed on the surface for fastening the plurality of first engaging elements to the plurality of second engaging elements.

Preferably, the plurality of limit plates are disposed on the two opposite edges of the surface.

Preferably, the first fixing device further has at least one fixing element connected to the surface for fixing the disk fixing structure to an operating device.

Preferably, the operating device is one of a computer apparatus and a multimedia player and the at least one fixing element is a screw hole.

Preferably, the second fixing device further includes a resilient element for urging against the disk while the second fixing device is mounted on the first fixing device.

Preferably, the resilient element is a prestressed plate having an arcuate structure with an end extended downward

Preferably, the second fixing device is a top cover and further has two auxiliary plates respectively mounted on two opposite edges of the second fixing device which are relative to the front and rear ends of the disk, and each of the auxiliary plates includes a gap for passing therethrough a circuit line of the disk.

Preferably, the plurality of first engaging elements are notches, the plurality of second engaging element are fasteners, and the at least one protrusion is a bump.

Preferably, the second fixing device further includes at least one ribbed plate disposed thereon between the two lateral plates.

According to a fourth aspect of the present invention, a disk fixing structure containing a disk is provided. The disk fixing structure includes a first fixing device disposing thereon the disk and a second fixing device. The first fixing device has two opposite edges corresponding to two sides of the disk and at least one first engaging elements connecting thereto each of the two opposite edges. The second fixing device has two lateral plates and at least one second engaging element disposed on each of the lateral plates for engaging with the at least one first engaging element, wherein the second fixing device further has a resilient element for urging against the disk while the second fixing device is mounted on the first fixing device, wherein the two lateral plates are respectively mounted on opposite edges of the second fixing device.

Preferably, he first fixing device further has a surface and at least one protrusion, and the at least one protrusion is mounted on the surface and lodged in at least one hole in a bottom of the disk.

According to a fifth aspect of the present invention, a disk fixing structure containing a disk having at least one hole in a bottom thereof is provided. The disk fixing structure includes a first fixing device and a second fixing device engaging with the first fixing device to contain the disk therein. The first fixing device has a receptacle disposing thereon the disk and at least one protrusion mounted thereon for being lodged in the at least one hole. Further, the second fixing device has a resilient element for urging against the disk while the first fixing device is mounted on the second fixing device.

Preferably, the first fixing device is a base and has two opposite lateral plates and a plurality of first engaging elements connected thereto for engaging with the second fixing device, and the two opposite lateral plates correspond to two sides of the disk.

Preferably, the second fixing device is a top plate and further has a plurality of second engaging elements corresponding to the two sides of the disk and used for engaging with the plurality of first engaging elements so as to engage the base with the top plate.

Preferably, the plurality of first engaging elements are fasteners and the plurality of second engaging elements are notches.

Preferably, the first fixing device further has two auxiliary plates disposed respectively at the ends of the two oppositely lateral plates and corresponding to the front and rear ends of the disk, and each of the two auxiliary plates includes a gap for passing therethrough a circuit line of the disk.

Preferably, the first fixing device further has at least one ribbed plate disposed on an inside of each of the two lateral plates for supporting a fixture of the disk.

Preferably, the first fixing device is a base and further has a plurality of first engaging elements located on two opposite edges of the receptacle which correspond to two sides of the disk.

Preferably, the second fixing device is a top cover and further includes two oppositely lateral plates and a plurality of second engaging elements connected thereto for engaging with the plurality of first engaging elements.

The above contents and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is an exploded view showing a disk fixing structure according to a first preferred embodiment of the present invention;

FIG. 2 is a schematic view showing an assembly of the disk fixing structure in FIG. 1;

FIG. 3 is a cross-sectional view showing the disk fixing structure in FIG. 2 along the A-A′ line;

FIG. 4 is another cross-sectional view showing the disk fixing structure in FIG. 2 along the B-B′ line; and

FIG. 5 is an exploded view showing a disk fixing structure according to a second preferred embodiment of the present invention.

### DETAILED DESCRIPTION OF THE PREFERRED EMBODIMENTS

The present invention will now be described more specifically with reference to the following embodiment. It is to be noted that the following descriptions of preferred embodiment of this invention are presented herein for purposes of illustration and description only; it is not intended to be exhaustive or to be limited to the precise form disclosed.

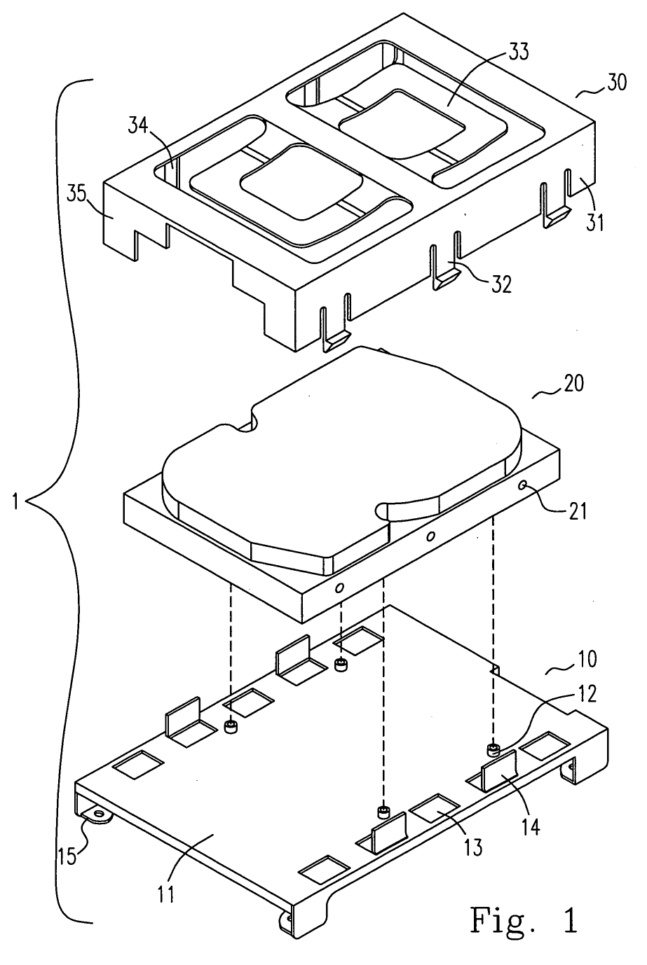

Please refer to FIG. 1, which is an exploded view showing a disk fixing structure 1 according to a first preferred embodiment of the present invention. The disk fixing structure 1 is used for containing a disk 20 and includes a first fixing device 10 and a second fixing device 30. The first fixing device 10 has a surface or receptacle 11 (referred to as the surface 11 hereinafter) and at least one protrusion 12. The disk 20 has a plurality of screw holes 21 in two laterals thereof and at least one hole in a bottom thereof. The surface 11 is used for disposing thereon the disk 20 and the at least one protrusion 12 is mounted on the surface 11 for being lodged in the at least one hole so as to assist the disk 20 orientated in the surface 11. Besides, the first fixing device 10 further includes a plurality of first engaging elements 13 arranged on each of two opposite edges of the surface 11 which correspond to two sides of the disk 20. The second fixing device 30 has two lateral plates 31 opposite to each other, and a plurality of second engaging elements 32 disposed on each of the two lateral plates 32, and engaging with the plurality of first engaging elements 13. Furthermore, the second fixing device 30 further includes a resilient element 33 in a top of the second fixing device 30 for urging against the disk 20 while the second fixing device 30 is mounted on the first fixing device 10, so as to enhance the stability of the disk 20 in the disk fixing structure 1. Thus, the disk 20 would be fixed without screwing the screw holes 21 in the laterals of the disk 20. Further, the first fixing device 10 further has at least one fixing element 15 connected to the surface 11 and bent downward for fixing the disk fixing structure 1 to an operating device. The operating device is one of a computer apparatus and a multimedia player.

Furthermore, the first engaging element 13 is a notch, the second engaging element 32 is a fastener, so that they are engaged with each other. In addition, the first fixing device 10 further has a plurality of limit plates 14 disposed on the two opposite edges of the surface 11, i.e. near by the first engaging elements 13, for fastening the plurality of first engaging elements 13 to the plurality of second engaging elements 32. Accordingly, while the second fixing device 30 is mounted on the first fixing device 10, the location which the second fixing device 30 is mounted therein will be limited due to the design of the limit plate 14. Hence the second fixing device 30 can be quickly and accurately engaged with the first fixing device 10 without any deviation.

Thus, the disk 20 would be securely disposed on the disk fixing structure 1. Since the disk fixing structure 1 is disposed on the operating device, the strength for bearing collision and vibration, i.e. the drop test and the vibration test, in the operating device would be greatly enhanced.

Further, the function in the protrusion 12 is used for assisting the disk 20 to be positioned in the surface 11 based on the mentioned description and its another function is used for strengthening the strength for bearing collision and vibration in the disk fixing structure 1. Moreover, the second fixing device 30 further includes at least one ribbed plate 34 disposed on an inside of each of the two lateral plates 31. Based on such design, the fringe of the ribbed plate 34 is just about contacted to the disk 20 for supporting a fixture of the disk 20 in the disk fixing structure 1. Besides, the second fixing device 30 further has two auxiliary plates 35 respectively mounted on two opposite edges of the second fixing device 30, i.e. disposed respectively at the ends of the two oppositely lateral plates 31, and corresponding to the front and rear ends of the disk 20. Each of the two auxiliary plates 35 includes a gap for passing therethrough a circuit line of the disk 20.

In addition, the first fixing device 10 is a base and the second fixing device 30 is a top cover, correspondingly. The protrusion 12 is a bump. The fixing element 15 could be a screw hole. The resilient element 33 is a prestressed plate having an arcuate structure with an end extended downward and has a resilience. Thus, a downward prestressed pressure to the disk 20 could be generated while the first fixing device 10, the disk 20 and the second fixing device 30 are assembled to be the disk fixing structure 1. This downward prestressed pressure can be used for urging against the disk 20 and reducing the noise generated from the disk 20. Therefore, according to the mentioned description, the assembly for the present invention is not screwed except that the present fixing structure 1 is screwed to the operating device.

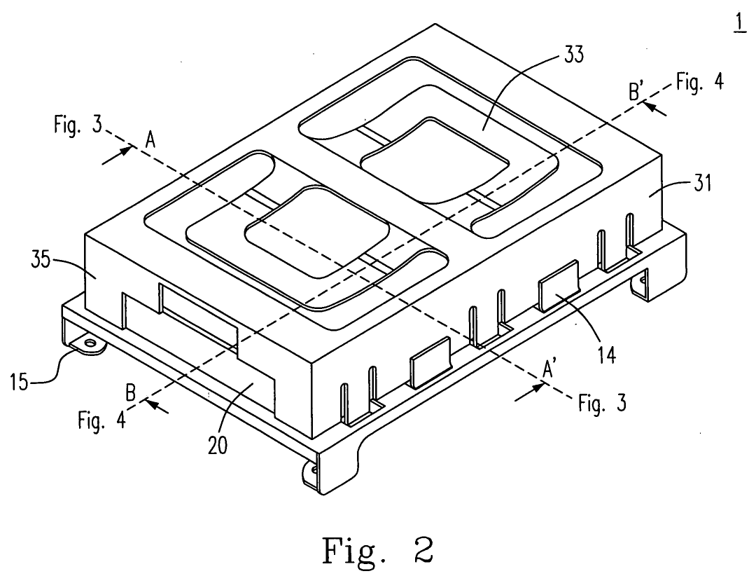

Please refer to FIG. 2, which is an assembly of the disk fixing structure in FIG. 1. In FIG. 2, the limit plate 14 of the first fixing device 10 is located on the outside of the lateral plate 31 of the second fixing device, and the disk 20 could be surrounded by the two lateral plates 31 and the two auxiliary plates 35.

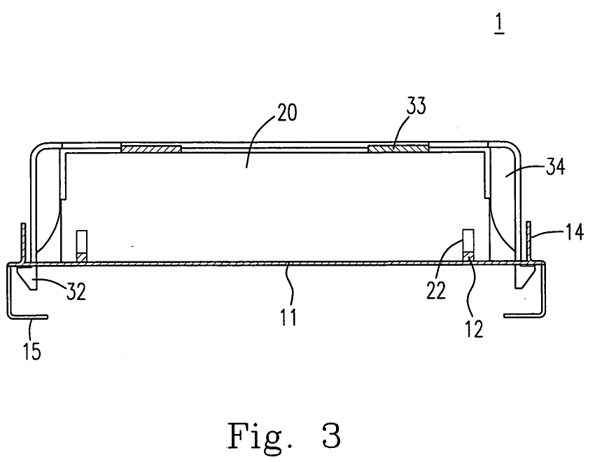

Please refer to FIG. 3, which is a cross-sectional view showing the disk fixing structure in FIG. 2 along the A-A′ line. In FIG. 3, the protrusion 12 is lodged in the hole 22 in the bottom of the disk 20, and the second engaging element 32 is penetrated through the surface 11. Further, the resilient element 33 is deposited on the top of the disk 20 for urging against the disk 20, and the ribbed plate 34 is just about contacted to the disk 20. Accordingly, the disk 20 is difficult to be shifted based on the mentioned design.

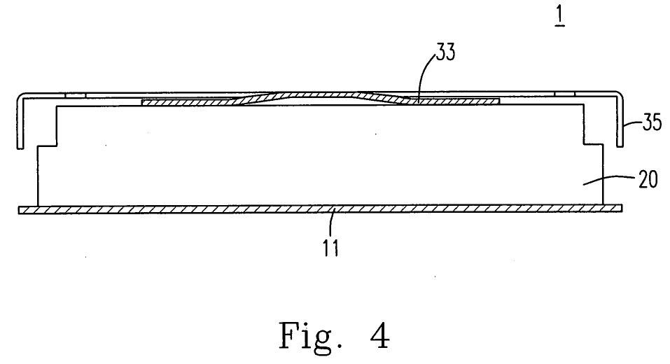

Please refer to FIG. 4, which is a cross-sectional view showing the disk fixing structure in FIG. 2 along the B-B′ line. In FIG. 4, the resilient element 33 includes an arcuate structure with two ends extended downward. Thus, the arcuate structure includes the appropriate resilience to generate a downward prestressed pressure for urging against the disk 20. Further, the two auxiliary plates 35 are disposed respectively relative to the front and rear ends of the disk 20 in order to the unexpected movement for the disk 20.

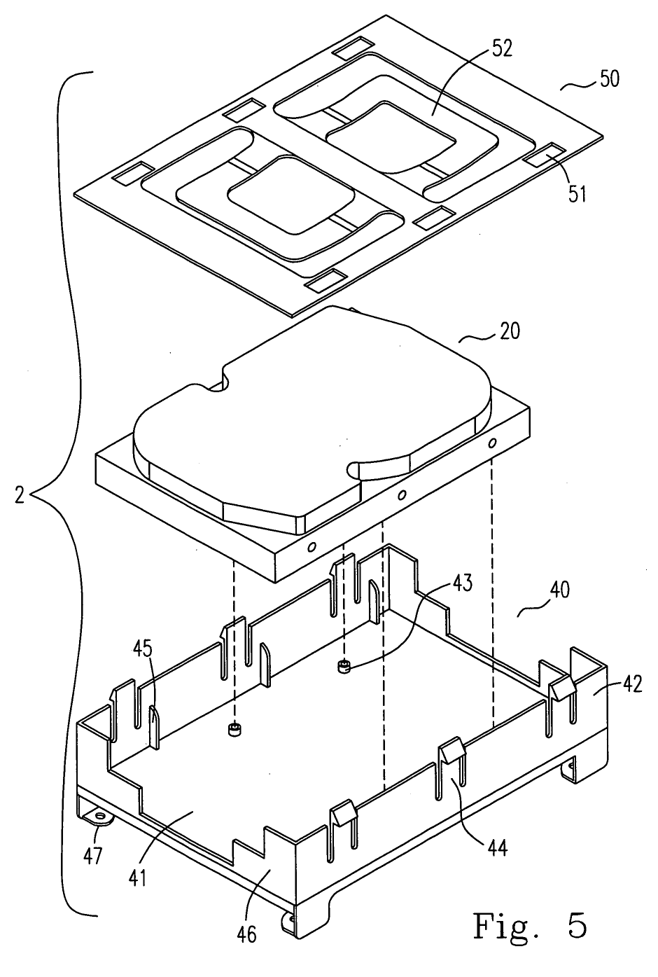

Please refer to FIG. 5, which is an exploded view showing a disk fixing structure according to a second preferred embodiment of the present invention. The some arrangement in the disk fixing structure 2 of the second preferred embodiment is similar with those in the disk fixing structure 1 of the first preferred embodiment. That is to say, a first fixing device 40 includes at least one fixing element 47 connected to a surface 41 and bent downward for fixing the disk fixing structure 2 to an operating device, and a second fixing device 50 has a resilient element 52 for urging against the disk 20 while the second fixing device 50 is mounted on the first fixing device 40. The difference between the disk fixing structure 2 of the second preferred embodiment and the disk fixing structure 1 of the first preferred embodiment is that two opposite lateral plates 42 and two auxiliary plates 45 are deposited on the first fixing device 40. Thus, the first fixing device 40 is a base and the second fixing device 50 is a top plate. Further, there is at least one ribbed plate 46 disposed on an inside of each of the two lateral plates 42 for supporting a fixture of the disk. In addition, a plurality of first engaging elements 44 of the first fixing device 40 are fasteners and a plurality of second engaging elements 51 of the second fixing device are notches since the lateral plate 42 in the second preferred embodiment is connected thereto the first fixing device 40. During the assembling the assembling process of the disk fixing structure 2, the disk 20 is mounted on the first fixing device 40 corresponding to at least one protrusion 43 and the ribbed plate 46. Then, the second engaging elements 51 of the second fixing device 50 are engaged with the first engaging elements 44 of the first fixing device 40, whereby the disk fixing structure 2 for containing the disk 20 would be achieved.

Therefore, it is understood that the present disk fixing structure could provide an integrated arrangement for the first fixing device, the disk and the second fixing device to simplify the process for assembling or disassembling the disk in the operating device. Furthermore, according to the present disk fixing structure, the stability for the disk in the operating device still is kept and the strength for bearing collision and vibration in the operating device would be greatly enhanced. Thus, both of the assembly and disassembly rates and the collision and vibration strengths would be considered by the present invention. Furthermore, the first fixing device and the second fixing device are combined by engaging with each other without screwing, so as to contain the disk. In addition, the present invention further provides at least one protrusion and a resilient element to assist the stability of the present disk fixing structure

While the invention has been described in terms of what are presently considered to be the most practical and preferred embodiments, it is to be understood that the invention need not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A disk fixing structure containing a disk having at least one hole in a bottom thereof, comprising:
a first fixing device having:
a surface disposing thereon the disk;
at least one protrusion mounted on the surface for being lodged in the at least one hole; and
a plurality of first engaging elements arranged on each of two opposite edges of the surface which correspond to two sides of the disk; and
a second fixing device having:
two lateral plates opposite to each other; and
a plurality of second engaging elements disposed on each of the two lateral plates, and engaging with the plurality of first engaging elements.

2. The disk fixing structure according to claim 1, wherein the first fixing device is a base and further has a plurality of limit plates disposed on the surface for fastening the plurality of first engaging elements to the plurality of second engaging elements.

3. The disk fixing structure according to claim 2, wherein the plurality of limit plates are disposed on the two opposite edges of the surface.

4. The disk fixing structure according to claim 1, wherein the first fixing device further has at least one fixing element connected to the surface for fixing the disk fixing structure to an operating device.

5. The disk fixing structure according to claim 4, wherein the operating device is one of a computer apparatus and a multimedia player and the at least one fixing element is a screw hole.

6. The disk fixing structure according to claim 1, wherein the second fixing device further includes a resilient element for urging against the disk while the second fixing device is mounted on the first fixing device.

7. The disk fixing structure according to claim 6, wherein the resilient element is a prestressed plate having an arcuate structure with an end extended downward.

8. The disk fixing structure according to claim 1, wherein the second fixing device is a top cover and further has two auxiliary plates respectively mounted on two opposite edges of the second fixing device which are relative to the front and rear ends of the disk, and each of the auxiliary plates includes a gap for passing therethrough a circuit line of the disk.

9. The disk fixing structure according to claim 1, wherein the plurality of first engaging elements are notches, the plurality of second engaging element are fasteners, and the at least one protrusion is a bump.

10. The disk fixing structure according to claim 1, wherein the second fixing device further includes at least one ribbed plate disposed thereon between the two lateral plates.

11. A disk fixing structure containing a disk, comprising:
a first fixing device disposing thereon the disk, and having two opposite edges corresponding to two sides of the disk and at least one first engaging elements connecting thereto each of the two opposite edges; and
a second fixing device having two lateral plates and at least one second engaging element disposed on each of the lateral plates for engaging with the at least one first engaging element, wherein the second fixing device further has a resilient element for urging against the disk while the second fixing device is mounted on the first fixing device, wherein the two lateral plates are respectively mounted on opposite edges of the second fixing device.

12. The disk fixing structure according to claim 11, wherein the first fixing device further has a surface and at least one protrusion, and the at least one protrusion is mounted on the surface and lodged in at least one hole in a bottom of the disk.

13. A disk fixing structure containing a disk having at least one hole in a bottom thereof, comprising:
a first fixing device having a receptacle disposing thereon the disk and at least one protrusion mounted thereon for being lodged in the at least one hole; and
a second fixing device engaging with the first fixing device to contain the disk therein, wherein the second fixing device has a resilient element for urging against the disk while the first fixing device is mounted on the second fixing device.

14. The disk fixing structure according to claim 13, wherein the first fixing device is a base and has two opposite lateral plates and a plurality of first engaging elements connected thereto for engaging with the second fixing device, and the two opposite lateral plates correspond to two sides of the disk.

15. The disk fixing structure according to claim 14, wherein the second fixing device is a top plate and further has a plurality of second engaging elements corresponding to the two sides of the disk and used for engaging with the plurality of first engaging elements so as to engage the base with the top plate.

16. The disk fixing structure according to claim 15, wherein the plurality of first engaging elements are fasteners and the plurality of second engaging elements are notches.

17. The disk fixing structure according to claim 15, wherein the first fixing device further has two auxiliary plates disposed respectively at the ends of the two oppositely lateral plates and corresponding to the front and rear ends of the disk, and each of the two auxiliary plates includes a gap for passing therethrough a circuit line of the disk.

18. The disk fixing structure according to claim 15, wherein the first fixing device further has at least one ribbed plate disposed on an inside of each of the two lateral plates for supporting a fixture of the disk.

19. The disk fixing structure according to claim 13, wherein the first fixing device is a base and further has a plurality of first engaging elements located on two opposite edges of the receptacle which correspond to two sides of the disk.

20. The disk fixing structure according to claim 19, wherein the second fixing device is a top cover and further includes two oppositely lateral plates and a plurality of second engaging elements connected thereto for engaging with the plurality of first engaging elements.
